(19) United States
(12) Patent Application Publication
(10) Pub. No.: US 2006/0042059 A1
(43) Pub. Date: Mar. 2, 2006

(54) Vibration isolation system for a vacuum chamber

(75) Inventors: Ichiju Satoh, Tokyo (JP); Setsuji Shinoda, Tokyo (JP); Yoshinori Jono, Tokyo (JP); Tsutomu Nishihashi, Shizuoka (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: EBARA CORPORATION, Tokyo (JP)

(21) Appl. No.: 10/960,778

(22) Filed: Oct. 8, 2004

(30) Foreign Application Priority Data
Oct. 9, 2003 (JP) 2003-350388

(51) Int. Cl. H01L 21/00

(52) U.S. Cl. 29/25.01

(57) ABSTRACT

The present invention provides a vibration isolation system which can prevent transmission of vibration from a transfer unit or other unit to a vacuum chamber, and can accurately perform positioning of the vacuum chamber connected to an elastic member having a simple structure and a transfer space therein. The present invention includes a vacuum chamber (11) placed on a vibration isolation unit, a transfer chamber (13) having a transfer space through which a work is transferred into the vacuum chamber (11), an elastic member (15) for connecting the vacuum chamber (11) and the transfer chamber (13), an actuator (24, 24) for elastically supporting the vacuum chamber (11) with respect to a fixed-side member, a position sensor (22) for detecting a displacement of the vacuum chamber (11) with respect to the fixed-side member, and a control unit (23) for controlling the actuator (24) based on output of the position sensor.

### BACKGROUND OF THE INVENTION

1. Field of the Invention

The present invention relates to a vibration isolation system for a vacuum chamber, and more particularly to a vibration isolation system for use in a device processing apparatus for processing a work in a vacuum chamber connected to a fixed-side chamber. The present invention also relates to a vibration isolation system for use in a device processing apparatus for performing processes such as machining, assembling, inspection, and fabrication of a work under vacuum in a vacuum chamber connected to a fixed-side chamber. The present invention also relates to a device processing apparatus and device processing method for performing machining, assembling, inspection, and fabrication of a work with use of such a vibration isolation system.

2. Description of the Related Art

Microfabrication has recently been progressing in a semiconductor processing apparatus and the like. Such apparatuses are required to perform operations such as machining, assembling, inspection, and fabrication with an accuracy of micron order or less. In order to prevent particle contamination and molecular contamination, most of the apparatuses of this kind comprise a vacuum chamber so that the above operations are performed under vacuum. In this kind of vacuum chamber, there is an important theme of how to effectively isolate or damp (remove) vibration transmitted from an installation floor and vibration produced inside the apparatus.

As a kind of vacuum chamber having a vibration isolation unit, there has been known a semiconductor processing apparatus shown in FIGS. 11 and 12, for example. This apparatus comprises a processing unit 102 for performing various kinds of processes, such as machining and inspection, on a work W in a vacuum chamber 101.

Specifically, this semiconductor processing apparatus has a transfer chamber 103 and a load lock chamber 107 for a work W, which are adjacent to the vacuum chamber 101 so as to enable the apparatus to perform successive process. The vacuum chamber 101 and the transfer chamber 103 are connected through a gate valve 104 and a bellows 105, and the transfer chamber 103 and the load lock chamber 107 are connected through a gate valve 108. A robot 106 is provided in the transfer chamber 103 for transferring the work W between the vacuum chamber 101 and the load lock chamber 107. An elevating mechanism 110 is provided in the load lock chamber 107 for elevating and lowering a cassette 109 accommodating a number of works W.

The whole semiconductor processing apparatus including the vacuum chamber 101 and the transfer chamber 103 is placed on a vibration isolation unit 111, so that vibration from an installation floor G is damped.

However, if the whole apparatus is large in size, the vibration isolation unit 111 should also be large in size, causing an increase in construction cost. In view of such a drawback, there has been proposed a structure which only prevents vibration from being transmitted to the vacuum chamber 101 having a space in which highly accurate operations are performed, while the load lock chamber 107 and the transfer chamber 103 for introducing the work W are fixed to the floor.

In an example shown in FIG. 13, vibration isolation units 121 are attached only to the vacuum chamber 101. In this case, when the vacuum chamber 101 is evacuated, an attracting force (F) given by the following equation is produced:
F=A×(P₀−P₁),
where A is a cross section of the bellows 105, P₀ is an atmospheric pressure, and P₁ is an inner pressure of the vacuum chamber 101.

Since a horizontal stiffness of the vibration isolation units 121 is low, the vacuum chamber 101 is attracted to the transfer chamber 103 by the attracting force (F) indicated by an arrow in the drawing. Accordingly, a distance between the vacuum chamber 101 and the transfer chamber 103 is greatly changed.

Thus, it has been proposed to attach an additional bellows to the vacuum chamber 101 at opposite side of the transfer chamber 103 and to provide frames for maintaining a distance between the bellows disposed on both sides of the vacuum chamber 101, so that the attracting forces produced in these bellows by the pressure change in the vacuum chamber 101 are balanced (see Japanese patent No. 3051651, for example).

It has also been proposed to place only a processing unit in a vacuum chamber onto a vibration isolation unit while the vacuum chamber is fixed to a floor so that vibration does not influence the processing of the work (see Japanese laid-open publication No. 2002-015989, for example).

It has also been proposed to provide an air spring between a vacuum chamber and another vacuum chamber corresponding to the transfer chamber, which are connected through a bellows, so as to cancel the attracting force acting between the chambers under vacuum (see Japanese laid-open publication No. 2001-210576).

However, the vibration isolation apparatus disclosed in Japanese patent No.3051651 is problematic in that the frames having a high stiffness and the bellows having a block flange should be provided on both side surfaces of the apparatus, thus causing an increase in manufacturing cost. In addition thereto, unbalanced elasticity of the bellows may affect the position of the vacuum chamber.

The vibration isolation apparatus disclosed in Japanese laid-open publication No. 2002-015989 is also problematic in that vibration of a transfer unit is directly transmitted to a work. Further, vibration from outside the apparatus through the floor cannot be prevented from being transmitted to the work through the vacuum chamber having no vibration isolation unit, thus affecting the processing of the work.

The vibration isolation apparatus disclosed in Japanese laid-open publication No. 2002-210576 is also problematic in that the distance between the two vacuum chambers is changed depending on a degree of vacuum.

In addition to the above problems, the conventional vacuum chamber has the following problem: Generally, the vacuum chamber is evacuated by a vacuum pump, and a turbo-molecular pump is widely used as the vacuum pump in order to achieve a high vacuum. Since the turbo-molecular pump achieves a high vacuum by rotating an impeller at a high speed, vibration is continuously produced by the rotation of the impeller during the operation of the turbo-molecular pump. Therefore, in order to prevent the vibration of the turbo-molecular pump from being transmitted directly to the vacuum chamber, it has been customary to connect the turbo-molecular pump to the vacuum chamber through a bellows.

FIG. 14 shows a schematic view of a device processing apparatus having a conventional vibration isolation system. As shown in FIG. 14, a turbo-molecular pump 131 is connected to the vacuum chamber 101, and a dry vacuum pump 140 is connected downstream of the turbo-molecular pump 131. In this case, the turbo-molecular pump 131 is used in such a state that it is not fixed to the floor G and is simply suspended from the vacuum chamber 101 by a bellows 135. This is because of the following reason: When the vacuum chamber 101 is evacuated, the bellows 135 is compressed by the atmospheric pressure and thus an overall length thereof decreases. Therefore, if the turbo-molecular pump 131 is fixed to the floor G, an external force is exerted on the whole semiconductor processing apparatus, thus causing an adverse effect on the control performance of the vibration isolation units 121.

However, since the mechanical strength of the bellows 135 is generally low, if the impeller is suddenly locked due to failure of the turbo-molecular pump 131, the bellows 135 may possibly be broken and the turbo-molecular pump 131 may drop from the vacuum chamber 101.

Generally, the turbo-molecular pump, which realizes a clean vacuum atmosphere, employs magnetic bearings for supporting the impeller in a non-contact manner. A levitation position of the impeller is controlled based on active control. Since the turbo-molecular pump is shipped on the premise of being used in a fixed state, if the turbo-molecular pump is hung simply by the bellows 135, then the controlling of the impeller is not performed properly and thus an abnormal vibration may be caused. Accordingly, there arise a need to use a turbo-molecular pump having a control circuit adjusted exclusively for a hanging type.

### SUMMARY OF THE INVENTION

The present invention has been made in view of the above drawbacks. It is therefore an object of the present invention to provide a vibration isolation system which can prevent transmission of vibration from a transfer unit or other unit such as a vacuum pump to a vacuum chamber, and can accurately perform positioning of the vacuum chamber connected to an elastic member having a simple structure and a transfer space therein.

In order to solve the above drawbacks, according to the present invention, there is provided a vibration isolation system for a vacuum chamber, the system comprising: a vacuum chamber placed on a vibration isolation unit; a transfer chamber having a transfer space through which a work is transferred into the vacuum chamber, the transfer chamber being fixed to an installation floor; an elastic member for connecting the vacuum chamber and the transfer chamber, the elastic member having a transfer space therein; an actuator for elastically supporting the vacuum chamber with respect to a fixed-side member; a position sensor for detecting a displacement of the vacuum chamber with respect to the fixed-side member; and a control unit for controlling the actuator based on output of the position sensor.

According to the present invention, while the transfer chamber is fixed to the installation floor, the vacuum chamber is placed on the vibration isolation unit. This system has the elastic member, which has the transfer space therein, for connecting the vacuum chamber and the transfer chamber to each other and the actuator for supporting the vacuum chamber with respect to the fixed member. With this structure, when an attracting force is produced by the evacuation of the vacuum chamber to attract the vacuum chamber to the transfer chamber, the displacement of the vacuum chamber is detected, and then a biasing force, which is adjusted according to the detection information, against the attracting force is applied from the actuator to the vacuum chamber. Therefore, the forces applied to the vacuum chamber are cancelled, and hence the displacement of the vacuum chamber is quickly compensated and the vacuum chamber is thus returned to the original position. In this manner, the accurate positioning of the vacuum chamber with respect to the transfer chamber at the fixed side is performed. Because the vacuum chamber is placed on the vibration isolation unit and is connected to the transfer chamber through the actuator and the elastic member, the vibration from outside can be damped or reduced, and the vibration produced in the vacuum chamber itself can also be damped or reduced.

In the present invention, the control unit controls the actuator so as to keep the position of the vacuum chamber constant even when the pressure in the vacuum chamber is changed. It is preferable to provide a plurality of actuators disposed in parallel with the elastic member so as to compensate the rotational displacement of the vacuum chamber. With this structure, the positioning of the vacuum chamber can be preformed accurately at all times and the transfer unit (robot) can thus transfer a work stably and reliably. A pressure-controllable air spring is preferably used as the actuator. This can reduce or isolate the vibration and can achieve the accurate positioning of the vacuum chamber at a low cost. Alternatively, an electromagnetic actuator which controls a position of an object by a magnetic force of an electromagnet may be used as the above-mentioned actuator.

It is preferable to incorporate the vibration isolation system according to the present invention into a device processing apparatus. It is also preferable to execute a device processing method for fabricating a desirable device with use of such a device processing apparatus. Further, it is preferable to use the position sensor incorporated in the vibration isolation unit or the device processing apparatus.

According to another aspect of the present invention, there is provided a vibration isolation system for a vacuum chamber, the system comprising: a vacuum chamber placed on a vibration isolation unit; a fixed base to which a vacuum pump is to be fixed; a first elastic member for connecting the vacuum chamber and the vacuum pump; a first actuator for adjusting a relative position of the vacuum chamber with respect to the fixed base; a first position sensor for detecting a displacement of the vacuum chamber with respect to the fixed base; and a control unit for controlling the first actuator based on output of the first position sensor; wherein the fixed base is fixed to an installation floor.

According to the present invention, because the position of the vacuum pump (e.g., a turbo-molecular pump) can be kept constant during the operation thereof, the operational safety of the vacuum pump can be secured. Further, according to the present invention, even when the vacuum chamber is moved toward the vacuum pump by the suction force of the vacuum pump, the first actuator can return the vacuum chamber to its original position.

In a preferred aspect of the present invention, the vibration isolation system further comprises a transfer chamber having a transfer space through which a work is transferred into the vacuum chamber, the transfer chamber being fixed to the installation floor; a second elastic member for connecting the vacuum chamber and the transfer chamber, the second elastic member having a transfer space therein; a second actuator for elastically supporting the vacuum chamber with respect to a fixed-side member; a second position sensor for detecting a displacement of the vacuum chamber with respect to the fixed-side member; and a second control unit for controlling the second actuator based on output of the second position sensor.

In a preferred aspect of the present invention, the first control unit and the second control unit control the first actuator and the second actuator, respectively, so as to keep the position of the vacuum chamber constant even when a pressure in the vacuum chamber is changed.

### BRIEF DESCRIPTION OF THE DRAWINGS

FIG. 1 is a schematic front view showing an entire structure of a device processing apparatus for performing a device processing method, the apparatus having a vibration isolation system for a vacuum chamber according to the present invention;

FIG. 2 is a plan view of the device processing apparatus shown in FIG. 1;

FIG. 3 is a plan view showing a main part of the vibration isolation system which is roughly depicted for illustrating a function of the vibration isolation system;

FIG. 4 is a schematic plan view showing an entire structure of a device processing apparatus having a vibration isolation system according to another embodiment of the present invention;

FIG. 5 is a schematic front view showing an entire structure of a device processing apparatus having a vibration isolation system according to still another embodiment of the present invention;

FIG. 6 is a schematic front view showing an entire structure of a device processing apparatus having a vibration isolation system according to still another embodiment of the present invention;

FIG. 7 is a cross-sectional front view showing an entire structure of a device processing apparatus having a vibration isolation system according to still another embodiment of the present invention;

FIG. 8 is a view as viewed from a direction indicated by an arrow VIII shown in FIG. 7;

FIG. 9 is a cross-sectional front view showing a device processing apparatus having a vibration isolation system according to still another embodiment of the present invention;

FIG. 10 is a view as viewed from a direction indicated by an arrow X shown in FIG. 9;

FIG. 11 is a front view showing a structural example of a prior art;

FIG. 12 is a plan view showing the structural example shown in FIG. 11;

FIG. 13 is a front view illustrating the drawbacks of the prior art; and

FIG. 14 is a schematic cross-sectional view showing an entire structure of a device processing apparatus having a conventional vibration isolation system.

### DETAILED DESCRIPTION OF THE PREFERRED EMBODIMENTS

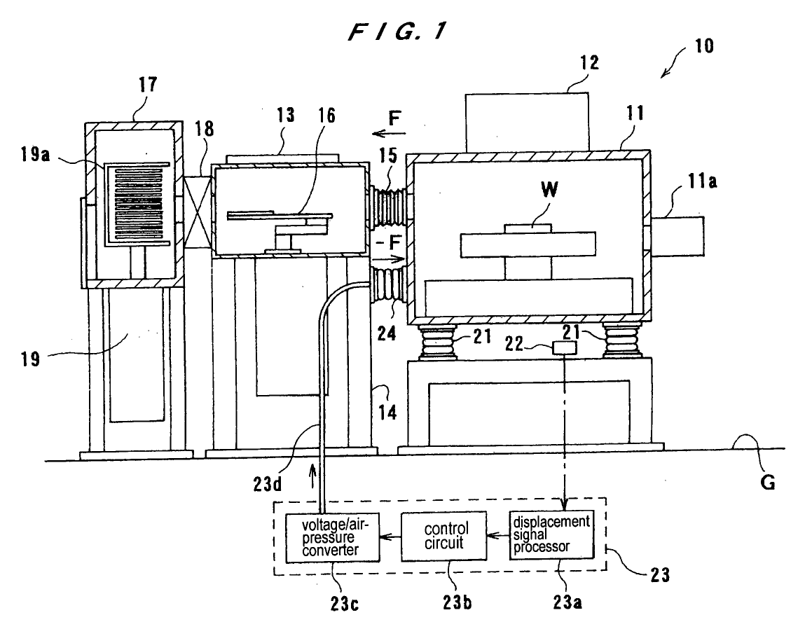

Hereinafter, embodiments of the present invention will be described with reference to the attached drawings. FIGS. 1 through 10 are views showing a device processing apparatus for performing various kinds of device processes. This device processing apparatus has a vibration isolation system according to the embodiments of the present invention. In these drawings, like or corresponding parts are denoted by the same reference numerals, and will not be described repetitively.

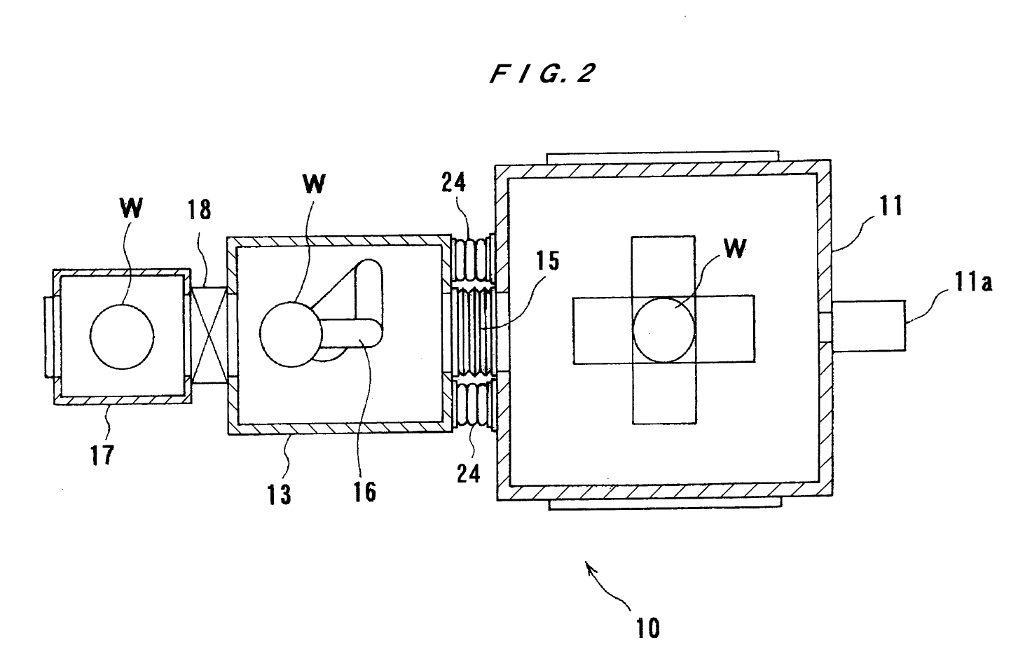

As shown in FIGS. 1 and 2, a semiconductor processing apparatus (device processing apparatus) 10 comprises a vacuum processing unit 12 having a vacuum chamber 11. The vacuum processing unit 12 is placed on vibration isolation units 21 each comprising an air spring. The vibration isolation units 21 isolate or damp vibration transmitted from a floor G to the vacuum processing unit 12.

The vacuum chamber 11 defines a space therein for processing a work W and has an outlet 11a formed in a side surface thereof. A non-illustrated vacuum pump for evacuating the vacuum chamber 11 is connected to the outlet 11a. While the vacuum chamber 11 is being evacuated, the vacuum processing unit 12 performs various kinds of processes such as machining and inspection of a work W, e.g., a semiconductor wafer, which has been transferred into the vacuum chamber 11.

This semiconductor processing apparatus 10 comprises a transfer chamber 13 adjacent to the vacuum chamber 11, and a load lock chamber 17 for removing a work W from a cartridge and housing the work W. The transfer chamber 13 has a transfer space through which a work W is transferred. A bellows (an elastic member) 15 having a transfer space therein for a work W is provided between the vacuum chamber 11 and the transfer chamber 13, and a gate valve 18 is provided between the transfer chamber 13 and the load lock chamber 17.

The gate valve 18 has a transfer opening which forms a transferring path for allowing a work W to pass therethrough, and has a function of closing the transfer opening so as not to allow a gas to leak therethrough. The bellows 15 is deformed, i.e., expanded and contracted, by an external force while keeping the transfer space therein which serves as a transferring path for a work W. Specifically, the bellows 15 allows the work W to be transferred between the vacuum chamber 11 and the transfer chamber 13 and connects the vacuum chamber 11 and the transfer chamber 13 to each other while keeping gastightness. Since the bellows 15 is deformed by the external force, the bellows 15 can isolate and damp the vibration from the transfer chamber fixed to the installation floor. In the same manner, the transfer chamber 13 and the load lock chamber 17 communicate with each other through the gate valve 18 in a gastight manner, and the work W can be transferred between the transfer chamber 13 and the load lock chamber 17 through the gate valve 18. A spring constant of the bellows 15 is set to be small compared with a lateral stiffness of actuators 24, which will be described later, so that the bellows 15 does not retard the function of the actuators 24.

The load lock chamber 17 has an elevating mechanism 19 for elevating and lowering a cassette 19a in which a number of works W are accommodated. In the transfer chamber 13, a robot 16 is provided for removing a work W from the cassette 19a in the load lock chamber 17 to transfer the work W into the vacuum chamber 11 and removing the work W, which has been processed, from the vacuum chamber 11 to return the work W to the cassette 19a. With this structure, the semiconductor processing apparatus 10 can replace and process the works W successively while the vacuum chamber 11 is being decompressed (evacuated).

A position control device comprises a sensor (position sensor) 22 for detecting a relative displacement (horizontal displacement) of the vacuum chamber 11 placed on the vibration isolation units 21 which are the air springs, a control unit (control means) 23 for calculating the displacement of the vacuum chamber 11 with respect to the installation floor G based on the detection signal from the sensor 22 and positioning the vacuum chamber 11 to a target position, and a pair of actuators 24 and 24. The control unit (control means) 23 comprises a displacement signal processor 23a for processing the signal from the sensor 22, a control circuit (compensation circuit) 23b, and a voltage/air-pressure converter 23c. The voltage/air-pressure converter 23c and the actuators 24 and 24 are connected by an air pipe 23d.

The vacuum chamber 11 is installed on the floor G through the vibration isolation units 21, and the transfer chamber 13 and the load lock chamber 17 are installed directly on the floor G. The vibration isolation units 21 such as air springs damp or remove the vibration transmitted from the floor G to the vacuum chamber 11. The bellows 15 and the actuators 24 and 24 serve to horizontally connect the vacuum chamber 11 to the fixed side in a viscoelastic manner, and also serve to damp or remove the vibration transmitted from the floor G to the vacuum chamber 11.

This semiconductor processing apparatus 10 comprises one pair of the actuators 24 and 24 provided between the vacuum chamber 11 and a fixed-side member (fixed portion) 14. These actuators 24 and 24 are preferably pressure-controllable air springs. The actuators 24 and 24 are disposed horizontally in parallel with the bellows 15 so as to produce a biasing force (−F) directed in parallel with the expanding and contracting direction (i.e., displacement or deformation direction) of the bellows 15 which is disposed horizontally. The actuators 24 and 24 are disposed on both sides of the bellows 15 so as to interpose the bellows 15 therebetween when viewed from above. The actuators 24 and 24 serve as a biasing mechanism for applying the horizontal biasing force (−F) from the fixed side to the vacuum chamber 11.

The actuators 24 and 24, as with the bellows 15, isolate or reduce the vibration transmitted from the installation floor G to the vacuum chamber 11. Although the air spring is used as the actuator in this embodiment, the actuator is not limited to this type. Instead of or in addition to the air spring, an electromagnetic actuator utilizing a magnetic force of an electromagnet may be used. Further, although one pair of the actuators is used in this example, three or more actuators may be used. Combination of an air spring and an electromagnet may also be used. This structure can improve the capability of not only the positioning control but also the vibration control.

The control unit 23 functions as follows: The displacement signal processor 23a processes the detection signal from the sensor 22 to calculate the displacement of the vacuum chamber 11. The control circuit 23b controls the voltage/air-pressure converter 23c based on the calculated displacement so as to adjust an air pressure of the actuators 24 and 24 through the air pipe 23d. Specifically, the control circuit 23b drives the voltage/air-pressure converter 23c based on the displacement of the vacuum chamber 11 so as to adjust the air pressure, whereby the actuators 24 and 24 produce the biasing force (−F) and thus positions the vacuum chamber 11 to a predetermined target position. It is preferable to provide two sensors each for one of the actuators 24 and 24. With this arrangement, the sensors can detect the rotational displacement of the vacuum chamber. Therefore, by controlling the actuators 24 and 24, the vacuum chamber can be prevented from rotating and can thus keep the predetermined position.

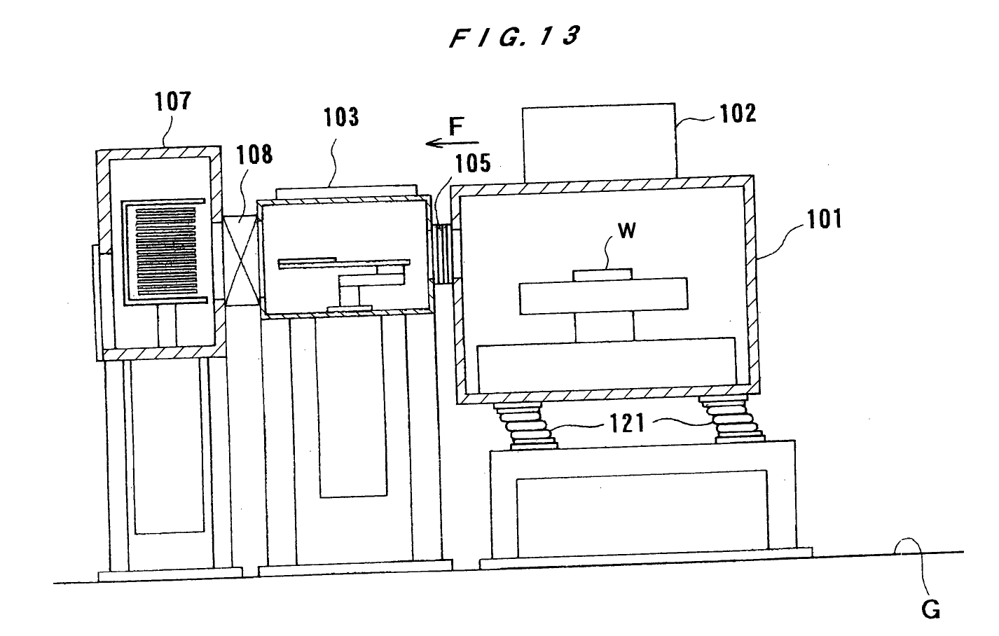

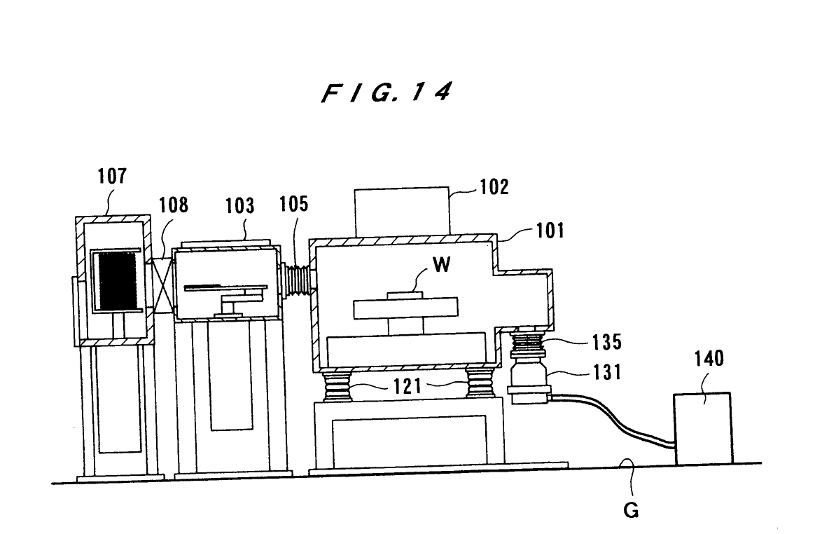

Next, the advantageous effect of the actuators 24 and 24 will be described. Since the vibration isolation units 21 are small in horizontal stiffness, when the vacuum chamber 11 is evacuated, the vacuum chamber 11 is attracted to the transfer chamber 13 due to a pressure difference between its internal pressure and the atmospheric pressure. The vacuum chamber 11 is thus moved in the horizontal direction to cause the bellows 15 to contract, as shown in FIG. 13.

The control unit 23 detects the horizontal displacement (the amount of shift) of the vacuum chamber 11 based on the detection signal from the sensor 22. Based on the detected displacement, the control unit 23 controls the actuators 24 and 24 so as to produce the biasing force (−F) which can cancel the attracting force (F) applied to the vacuum chamber 11. The vacuum chamber 11 is thus returned to the predetermined position (the target position) with respect to the installation floor G. In this manner, even when the vacuum chamber 11 is evacuated and the degree of vacuum (a pressure in the chamber) is changed, the vacuum chamber 11 can recover its displacement and is thus retuned to the predetermined position quickly.

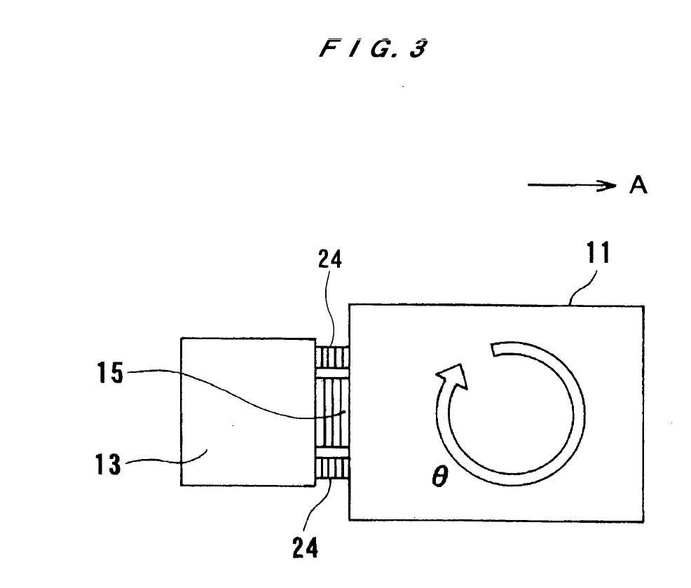

Since the actuators 24 and 24 are disposed on both sides of the bellows 15, it is possible to apply individual biasing forces to the side surface of the vacuum chamber 11 on the right-and-left sides of the bellows 15. With this structure, even when the vacuum chamber 11 rotates as shown in FIG. 3, the actuators 24 and 24 can produce the right-and-left biasing forces which are different in magnitude, and can thus compensate the displacement of the vacuum chamber 11 with respect to the installation floor G not only in A direction but also in θ direction in a horizontal plane. Although the actuators 24 and 24 are disposed on right-and-left sides of the bellows 15 in this embodiment in order to adjust the position of the vacuum chamber 11 in the θ direction in the horizontal plane, the actuators may be disposed above the bellows 15 or at other positions so as to adjust the rotational position of the vacuum chamber 11 in a vertical plane

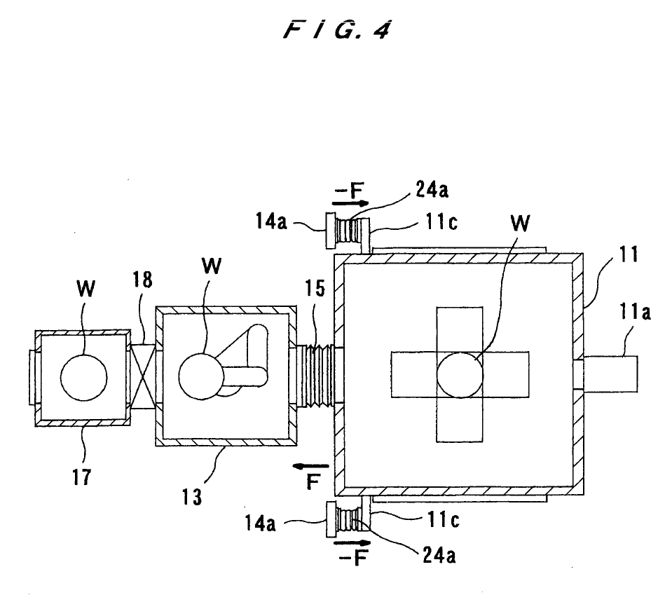

FIGS. 4 through 6 show another embodiment of actuators for adjusting the horizontal position of the vacuum chamber. FIG. 4 shows an example in which a pair of actuators 24a and 24a is provided on both sides of the vacuum chamber 11. Each of the actuators 24a has an end portion fixed to a vacuum-chamber-side member 11c and other end portion fixed to a fixed-side member 14a. When the vacuum chamber 11 is evacuated, the attracting force is produced between the vacuum chamber 11 and the transfer chamber 13. At this time, the actuators 24a, such as pressure-controllable air springs, produce an opposing force against the attracting force, and thus position the vacuum chamber 11 to the predetermined position. The actuators are not limited to the pressure-controllable air springs. Electromagnetic actuators and the like may also be used as the actuators.

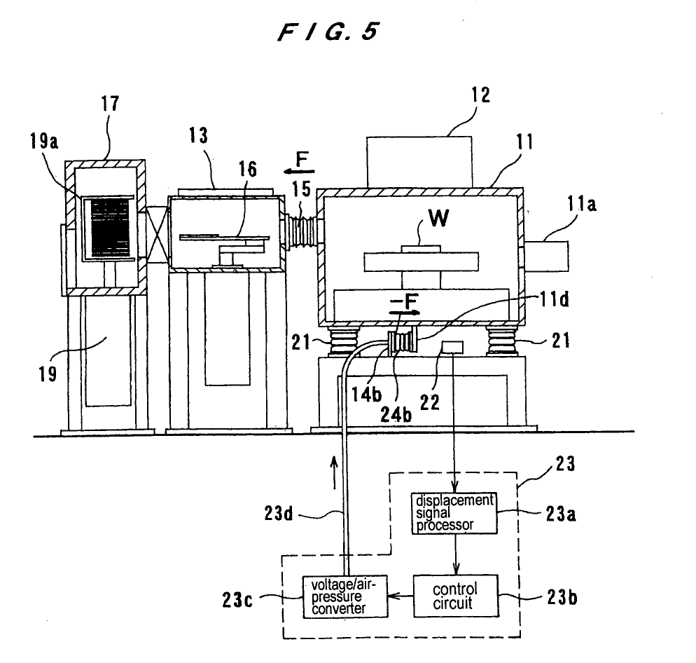

FIG. 5 shows an embodiment in which actuators are attached to a lower surface of the vacuum chamber. In this embodiment, fixed members lid are provided on the lower surface of the vacuum chamber 11, and actuators 24b and 24b, which are pressure-controllable air springs, are attached to fixed-side members 14b. Although only one actuator 24b is shown in the drawing, two actuators 24b and 24b are provided on both sides of the bellows 15 through which the attracting force is produced by the evacuation, when viewed from above. The control circuit 23b generates a signal for returning the vacuum chamber 11 to the predetermined target position based on the horizontal displacement detected by the displacement sensor 22. The voltage is converted into the air pressure, and then a necessary pressure is produced in the actuators 24b and 24b through the air pipe 23d. In this manner, the opposing force against the force which is produced by the evacuation is produced, thereby positioning the vacuum chamber 11 to the predetermined target position. Since the two actuators 24b and 24b are disposed on both sides of an extension line of the bellows 15, the actuators 24b and 24b can cancel a rotating force and can thus position the vacuum chamber 11 to the predetermined proper position.

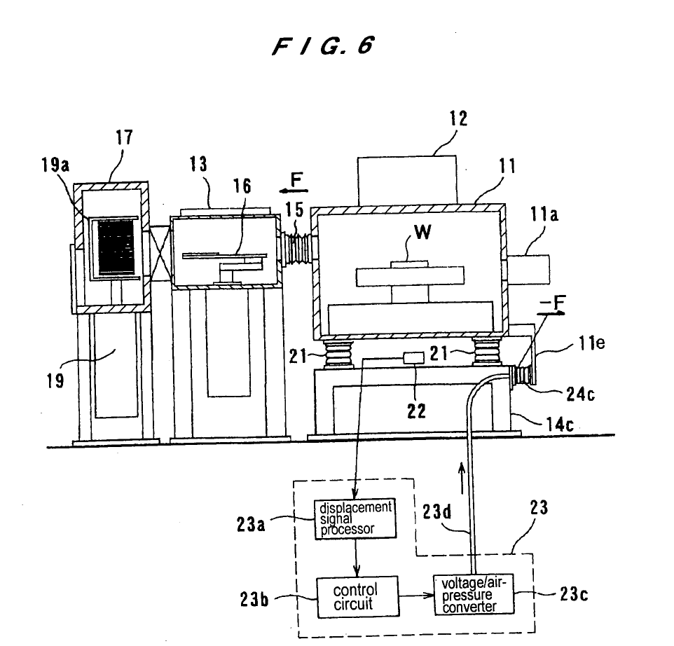

FIG. 6 shows an embodiment in which actuators are attached to an opposite surface (rear surface), which is opposite to the bellows, of the vacuum chamber. In this embodiment, fixed members 11e are provided on the opposite surface (rear surface), which is opposite to the bellows 15, of the vacuum chamber 11. Actuators 24c and 24c, which are pressure-controllable air springs, are provided between the fixed members 11e and a fixed-side member 14c. Although only one actuator 24c is shown in the drawing, two actuators 24c and 24c are provided on both sides of a line extending in a direction (a direction along the bellows 15) of the attracting force produced by the evacuation, when viewed from above. The control circuit 23b generates a control signal for returning the vacuum chamber 11 to the predetermined target position based on the displacement signal from the displacement sensor 22 which detects the displacement of the vacuum chamber 11. The voltage is converted into the air pressure, and then a necessary pressure is produced in the actuators 24c and 24c through the air pipe 23d. In this manner, the opposing force against the force which is produced by the evacuation is produced, thereby positioning the vacuum chamber 11 to the predetermined target position. Since the two actuators 24c and 24c are disposed on both sides of an extension line of the bellows 15, the actuators 24c and 24c can cancel a rotating force and can thus position the vacuum chamber 11 to the predetermined proper position.

If the actuators malfunction, the actuators may press the fixed side with a large force to change a position of the fixed member. Thus, it is preferable to install a control program so as not to allow the actuators to apply the pressing force larger than a certain value. Further, it is preferable to provide a regulator on an inlet of the air spring actuator so that a pressure larger than a certain degree is not produced in the actuator. It is also preferable to provide a mechanical stopper so that the air spring actuator does not expand beyond a certain degree.

There is a case where the vibration isolation units 21 incorporate a displacement sensor which can detect the position of the vacuum chamber. In such a case, the displacement sensor incorporated in the vibration isolation units 21 may be used to detect the horizontal displacement of the vacuum chamber. By using the existing sensor, the position control system for the vacuum chamber can be constructed without providing a dedicated sensor, resulting in a low cost. As with the above case, there is a case where the vacuum chamber incorporates a position sensor. In this case also, the position sensor incorporated in the vacuum chamber can be used to detect the displacement of the vacuum chamber.

The semiconductor processing apparatus (device processing apparatus) according to the embodiments can be used to perform certain processes such as machining, assembling, inspection, and fabrication of a semiconductor device under vacuum. The apparatus can employ the device processing method for performing desired operations on a work W disposed in the vacuum chamber 11. Even when the apparatus is applied to a semiconductor process where microfabrication has been progressing, since the vacuum chamber 11 is positioned with high accuracy, the work W such as a wafer can be transferred within an accuracy of 1/10 mm. Therefore, highly accurate processes can be performed on the work W.

As described above, the attracting force (F) applied to the vacuum chamber 11 is cancelled by the biasing force (−F) produced by the actuators 24, 24a, 24b and 24c. Accordingly, the vacuum chamber 11 can be quickly returned to the predetermined target position, and the vibration of the robot 16 in the transfer chamber 13 can be damped or reduced effectively. In this manner, it is possible to remove the vibration of the vacuum chamber 11, position the vacuum chamber 11 accurately, and transfer the work W smoothly and accurately with a simple structure having the actuators 24, 24a, 24b and 24c. As a result, the work W can be efficiently transferred into and out of the vacuum chamber 11 which has been accurately positioned, whereby throughput of the semiconductor processing apparatus, which performs high-precision processes such as machining and inspection, can be improved.

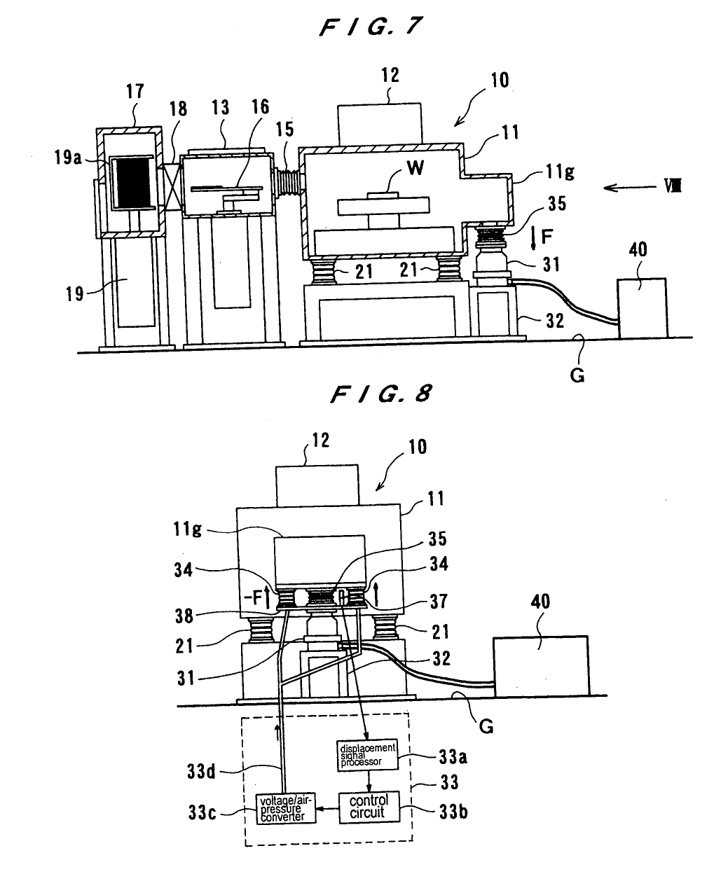

Next, another embodiment of the present invention will be described with reference to FIGS. 7 and 8. FIG. 7 is a cross-sectional front view showing an entire structure of a device processing apparatus having a vibration isolation system according to another embodiment of the present invention, and FIG. 8 is a view as viewed from a direction indicated by an arrow VIII shown in FIG. 7.

As shown in FIG. 7, a turbo-molecular pump (i.e., a vacuum pump) 31 is connected to the lower surface of the vacuum chamber 11 through a bellows (a first elastic member) 35. Specifically, an upper portion of the bellows 35 is fixed to a lower surface of a projecting portion 11g projecting outwardly from a sidewall of the vacuum chamber 11, and a lower portion of the bellows 35 is connected to a suction mouth of the turbo-molecular pump 31. A dry vacuum pump 40 is disposed downstream of the turbo-molecular pump 31. The turbo-molecular pump 31 is fixed to an upper surface of a fixed base 32, and the fixed base 32 and the dry vacuum pump 40 are fixed to the installation floor G. The turbo-molecular pump 31 communicates with the vacuum chamber 11 through the bellows 35 so that the vacuum chamber 11 is evacuated by the turbo-molecular pump 31.

According to this embodiment, since the turbo-molecular pump 31 is fixed to the installation floor G through the fixed base 32, the position (attitude) of the turbo-molecular pump 31 is kept constant during the operation. Therefore, the active control for supporting an impeller in a non-contact manner can be performed properly, and hence an abnormal vibration can be prevented from being caused and the operational safety of the turbo-molecular pump 31 can be secured.

As shown in FIG. 8, a pair of actuators (first actuators) 34 and 34 is disposed on both sides of the bellows 35 disposed vertically. Lower portions of these actuators 34 and 34 are attached to an upper surface of a mounting member 38 which is fixed to the turbo-molecular pump 31, and upper portions of the actuators 34 and 34 are attached to the lower surface of the projecting portion 11g of the vacuum chamber 11. Specifically, the actuators 34 and 34 are disposed in parallel with the bellows 35 and are located on both sides of the bellows 35 so as to interpose the bellows 35 therebetween.

A displacement sensor (a first position sensor) 37 is provided on the upper surface of the mounting member 38 so as to measure expansion and contraction of the bellows 35, i.e., a displacement of the vacuum chamber 11 with respect to the fixed base 32 (the installation floor G). A displacement signal from the displacement sensor 37 is input to a control unit (a first control unit) 33 comprising a displacement signal processor 33a, a control circuit 33b, and a voltage/air-pressure converter 33c. In this control unit 33, the displacement signal processor 33a processes the displacement signal from the displacement sensor 37 to calculate a displacement of the vacuum chamber 11, and the control circuit (e.g., PID compensating circuit) 33b controls the voltage/air-pressure converter 33c based on the calculated displacement. The voltage/air-pressure converter 33c supplies an air having a desired pressure to the actuators 34 and 34 through an air pipe 33d so that the actuators 34 and 34 produce a biasing force (−F) for canceling an attracting force (F) produced by the evacuating operation of the turbo-molecular pump 31. In this manner, a vertical position of the vacuum chamber 11 is kept constant by the actuators 34 and 34. The actuators 34 and 34 serve as a biasing mechanism for applying a vertical biasing force from the fixed side to the vacuum chamber 11.

Although pressure-controllable air springs are used as the actuators 34 and 34 in this embodiment, electromagnetic actuators may be used alternatively. Further, although one pair of actuators is used in this embodiment, three or more actuators may be used.

Although the turbo-molecular pump is used as a vacuum pump in this embodiment, another type of pump may be used. For example, a positive displacement dry pump may be used as the vacuum pump. Further, although a combination of the turbo-molecular pump 31 and the dry vacuum pump 40 is used in this embodiment, only a single vacuum pump (e.g., a turbo-molecular pump or a positive displacement dry pump) may be used.

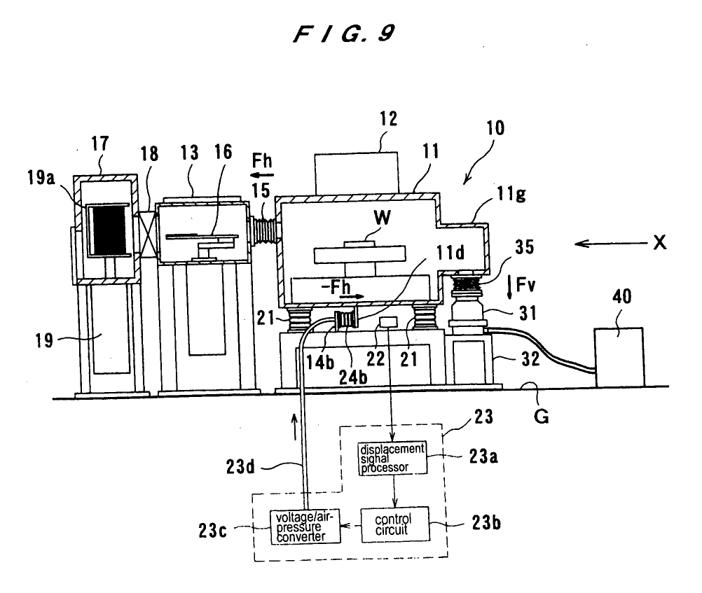

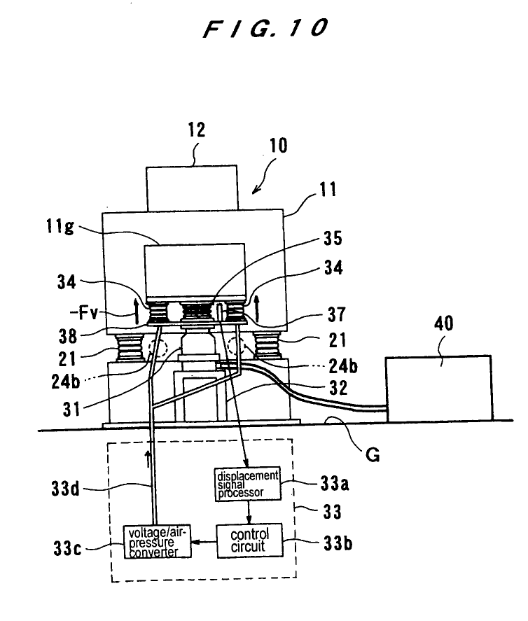

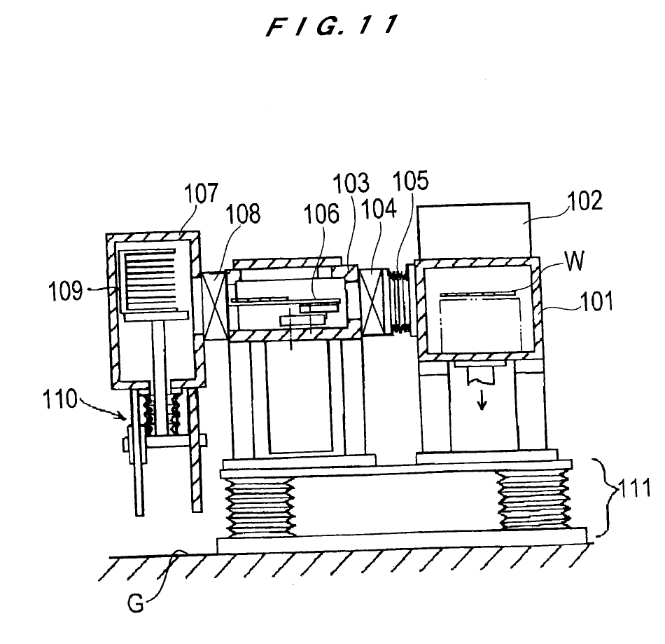

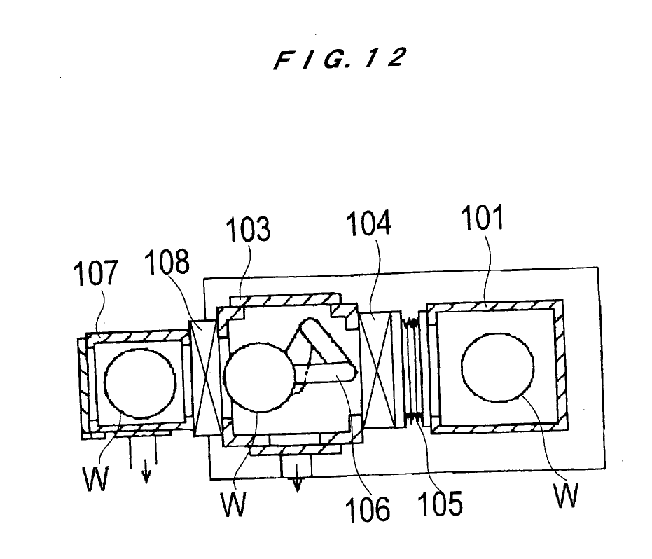

FIG. 9 is a cross-sectional front view showing a device processing apparatus having a vibration isolation system according to another embodiment of the present invention, and FIG. 10 is a view as viewed from a direction indicated by an arrow X shown in FIG. 9. A vibration isolation system of this embodiment has a combination structure comprising the actuators 24b and 24b and the control unit 23 shown in FIG. 5, and the actuators 34 and 34 and the control unit 33 shown in FIGS. 7 and 8. Specifically, as shown in FIGS. 9 and 10, the vibration isolation system comprises the actuators 24b and 24b and the control unit 23 for keeping the horizontal position of the vacuum chamber 11 constant, and the actuators 34 and 34 and the control unit 33 for keeping the vertical position of the vacuum chamber 11 constant. The respective components shown in FIGS. 9 and 10 are identical to those shown in FIGS. 5, 7 and 8, and will not be described below repetitively. The bellows 15, the actuator 24b, the displacement sensor 22, and the control unit 23 shown in FIG. 9 serve as a second elastic member, a second actuator, a second position sensor, and a second control unit, respectively.

According to the vibration isolation system of the present embodiment, the actuators 24b, 24b, 34 and 34 can produce forces (−Fh, −Fv) so as to cancel the horizontal force (Fh) and the vertical force (Fv) which are produced when the turbo-molecular pump 31 evacuates the vacuum chamber 11. Therefore, the vacuum chamber 11 can be kept constant in position. In this embodiment also, the position of the turbo-molecular pump (vacuum pump) 31 is fixed by the fixed base 32, and hence the operational safety of the turbo-molecular pump 31 can be secured.

The position of the second actuator is not limited to the position of the actuator 24b shown in FIG. 9. For example, the second actuator may be disposed at any of positions of the actuators illustrated in FIGS. 1 through 4, and 6.

In the above-mentioned embodiments, the bellows 15 is used as the elastic member for connecting the vacuum chamber 11 and the transfer chamber 13. However, the elastic member is not limited to the bellows. For example, an elastic material such as rubber having a transfer opening for a work W may be used. Even in the case where the transfer chamber is not provided, the concept of the present invention can be applied to the vacuum chamber mounted on the vibration isolation unit in the same manner as described above.

Although certain preferred embodiments of the present invention have been described, it should be understood that the present invention is not limited to the embodiments described above and various modifications may be made without departing from the scope of the technical concept thereof.

As described above, according to the present invention, it is possible to isolate or damp the vibration transmitted from the transfer unit and the floor. It is also possible to position the vacuum chamber accurately and transfer the work smoothly and accurately with a simple structure. As a result, the work can be efficiently transferred into and out of the vacuum chamber positioned accurately. Therefore, the throughput of the apparatus can be improved, and the device processing apparatus and method for performing accurate processes such as machining and inspection can be provided.

What is claimed is:

1. A vibration isolation system for a vacuum chamber, said system comprising:
a vacuum chamber placed on a vibration isolation unit;
a transfer chamber having a transfer space through which a work is transferred into said vacuum chamber, said transfer chamber being fixed to an installation floor;
an elastic member for connecting said vacuum chamber and said transfer chamber, said elastic member having a transfer space therein;
an actuator for elastically supporting said vacuum chamber with respect to a fixed-side member;
a position sensor for detecting a displacement of said vacuum chamber with respect to said fixed-side member; and
a control unit for controlling said actuator based on output of said position sensor.

2. A vibration isolation system according to claim 1, wherein said control unit controls said actuator so as to keep a position of said vacuum chamber constant even when a pressure in said vacuum chamber is changed.

3. A vibration isolation system according to claim 1, wherein a plurality of actuators are provided in parallel with said elastic member so as to compensate a rotational displacement of said vacuum chamber.

4. A vibration isolation system according to claim 1, wherein said actuator is a pressure-controllable air spring.

5. A vibration isolation system according to claim 1, wherein said position sensor is incorporated in said vibration isolation unit.

6. A device processing apparatus having a vibration isolation system for a vacuum chamber, said system comprising:
a vacuum chamber placed on a vibration isolation unit;
a transfer chamber having a transfer space through which a work is transferred into said vacuum chamber, said transfer chamber being fixed to an installation floor;
an elastic member for connecting said vacuum chamber and said transfer chamber, said elastic member having a transfer space therein;
an actuator for elastically supporting said vacuum chamber with respect to a fixed-side member;
a position sensor for detecting a displacement of said vacuum chamber with respect to said fixed-side member; and
a control unit for controlling said actuator based on output of said position sensor.

7. A device processing apparatus according to claim 6, wherein said position sensor is constructed using a sensor incorporated in said device processing apparatus.

8. A device processing method characterized in that a device is processed using a device processing apparatus according to claim 6.

9. A vibration isolation system for a vacuum chamber, said system comprising:
a vacuum chamber placed on a vibration isolation unit;
a fixed base to which a vacuum pump is to be fixed;
a first elastic member for connecting said vacuum chamber and the vacuum pump;
a first actuator for adjusting a relative position of said vacuum chamber with respect to said fixed base;
a first position sensor for detecting a displacement of said vacuum chamber with respect to said fixed base; and
a control unit for controlling said first actuator based on output of said first position sensor;
wherein said fixed base is fixed to an installation floor.

10. A vibration isolation system according to claim 9, further comprising:
a transfer chamber having a transfer space through which a work is transferred into said vacuum chamber, said transfer chamber being fixed to the installation floor;
a second elastic member for connecting said vacuum chamber and said transfer chamber, said second elastic member having a transfer space therein;
a second actuator for elastically supporting said vacuum chamber with respect to a fixed-side member;
a second position sensor for detecting a displacement of said vacuum chamber with respect to said fixed-side member; and
a second control unit for controlling said second actuator based on output of said second position sensor.

11. A vibration isolation system according to claim 10, wherein said first control unit and said second control unit control said first actuator and said second actuator, respectively, so as to keep the position of said vacuum chamber constant even when a pressure in said vacuum chamber is changed.
